(19) United States
(12) Patent Application Publication
(10) Pub. No.: US 2013/0049787 A1
(43) Pub. Date: Feb. 28, 2013

(54) METHOD OF TESTING STACKED SEMICONDUCTOR DEVICE STRUCTURE

(71) Applicants: Chi-Ming YI, Hsinchu County (TW); An-Hong Liu, Hsinchu County (TW); Hsiang-Ming Huang, Hsinchu County (TW); Yi-Chang Lee, Hsinchu County (TW)

(72) Inventors: Chi-Ming YI, Hsinchu County (TW); An-Hong Liu, Hsinchu County (TW); Hsiang-Ming Huang, Hsinchu County (TW); Yi-Chang Lee, Hsinchu County (TW)

(21) Appl. No.: 13/445,067

(22) Filed: Apr. 12, 2012

(30) Foreign Application Priority Data
Aug. 25, 2011 (TW) 100130478

(51) Int. Cl. G01R 31/00

(52) U.S. Cl. 324/756.03

(57) ABSTRACT

The present invention provides a method of testing a stacked semiconductor device structure. This method includes the following steps: providing a testing board having a plurality of testing points and a probe card; providing a substrate which is disposed on the testing board; providing a plurality of semiconductor devices; mounting and electrically connecting a first one of the semiconductor devices onto the substrate; mounting and electrically connecting a second one of the semiconductor devices onto the first one of the semiconductor devices; keeping the probe card in contact with the second one of the semiconductor devices for electrical testing; and repeating the steps of mounting and testing of the semiconductor devices until all of the semiconductor devices are tested. This method can ensure the integrity of electrical interconnections between the semiconductor devices of the stacked structure.

### BACKGROUND OF THE INVENTION

1. Field of the Invention

The present invention relates to a method of testing a stacked semiconductor device structure, and, more particularly, to a method of testing a stacked semiconductor device structure with through-silicon-vias (TSVs).

2. Description of the Prior Art

Semiconductor devices are widely used in developing modern technology products. Semiconductor devices such as chips or wafers are indispensably used in electronic apparatus pertaining to communication, computing, and networking technologies. Given the greatly increasing market demand for the aforesaid electronic products, semiconductor manufacturers are endeavoring to promptly and efficiently improve the manufacturing process of the semiconductor devices, and to offer sufficient chips to meet the market demand. Aiming at this goal, semiconductor devices are subject to tests during fabrication to ensure that the produced semiconductor devices function properly by eliminating the malfunctioned semiconductor devices so as to assure high production yield.

Typically, in fabricating a stacked semiconductor device structure, the semiconductor devices are separately subject to testing to make sure each of the devices functions properly before they are stacked together. After all the semiconductor devices have been stacked, the whole stacked structure is again subject to testing. Although each of the semiconductor devices is known in good condition prior to stacking, the whole stacked structure might still be malfunctioned as a result of any errors or problems generating during the stacking process, which may get more obvious when the semiconductor devices become smaller in form factor. In the stacking process, faulty electrical interconnection between any semiconductor devices can compromise the functionality of the whole stacked semiconductor device structure or even make the whole stacked semiconductor device structure totally fail. It thus will reduce the yield rate of the final semiconductor device package structure, and, more importantly, increase the production cost since the flawed products that may be caused by connection failure of only one semiconductor device with the remaining devices connected perfectly can only be sold at lower prices or even discarded. Hence, how to effectively ensure the proper function of the semiconductor devices after stacking, increase the yield rate of electronic products, and reduce a waste of resources has always been a major aim in the industry.

In view of this, it is important for the people in the industry to make improvement aiming at overcoming the drawbacks of conventional methods of testing stacked semiconductor device structures during a manufacturing process so as to conveniently test a stacked semiconductor device structure and economically minimize the manufacturing costs.

### SUMMARY OF THE INVENTION

To overcome the aforesaid drawbacks of the prior art, the present invention provides a method of testing a stacked semiconductor device structure. The method of testing a stacked semiconductor device structure includes the steps of:

(a) providing a testing board and a probe card, the testing board having a plurality of testing points, the probe card having a plurality of probes, the testing board and the probe card being respectively connected to a test device for sending and receiving a test signal;

(b) providing a substrate, the substrate being disposed on the testing board and having a plurality of first contacts and a plurality of second contacts, the first contacts and the second contacts being electrically conducted correspondingly, and the first contacts being electrically connected to the test points of the testing board;

(c) providing a plurality of semiconductor devices, each of the semiconductor devices having a plurality of first terminals and a plurality of second terminals, the first terminals and the second terminals being electrically conducted correspondingly, mounting a first one of the semiconductor devices onto the substrate, and electrically connecting the first terminals of the first one of the semiconductor devices to the second contacts of the substrate;

(d) mounting a second one of the semiconductor devices onto the first one of the semiconductor devices, and electrically connecting the first terminals of the second one of the semiconductor devices to the second terminals of the first one of the semiconductor devices;

(e) keeping the probes of the probe card in contact with the second terminals of the second one of the semiconductor devices for electrically testing the second one of the semiconductor devices; and

(f) repeating step (d) and step (e) until all of the semiconductor devices are tested.

The present invention further provides a method of testing a stacked semiconductor device structure. The method of testing a stacked semiconductor device structure includes the steps of:

(a) providing a testing board and a probe card, the testing board having a plurality of testing points, the probe card having a plurality of probes, the testing board and the probe card being respectively connected to a test device for sending and receiving a test signal;

(b) providing a substrate, the substrate having a plurality of first contacts and a plurality of second contacts, the first contacts and the second contacts being electrically conducted correspondingly, and the first contacts adapted to be probed by the probe card;

(c) providing a plurality of semiconductor devices, each of the semiconductor devices having a plurality of first terminals and a plurality of second terminals, the first terminals and the second terminals being electrically conducted correspondingly, mounting a first one of the semiconductor devices onto the substrate, and electrically connecting the first terminals of the first one of the semiconductor devices to the second contacts of the substrate;

(d) mounting a second one of the semiconductor devices onto the first one of the semiconductor devices, and electrically connecting the first terminals of the second one of the semiconductor devices to the second terminals of the first one of the semiconductor devices;

(e) electrically connecting the second terminals of the second one of the semiconductor devices to the testing points of the testing board, and keeping the probes of the probe card in contact with the first contacts of the substrate for electrically testing the second one of the semiconductor devices; and

(f) repeating step (d) and step (e) until all of the semiconductor devices are tested.

Hence, a primary objective of the present invention is to provide a method of testing a stacked semiconductor device structure. The method of testing a stacked semiconductor device structure involves subjecting each of the semiconductor devices to the electrical testing immediately after each of the semiconductor device being stacked. The method of testing ensures that the semiconductor devices have normal electrical signals after being stacked, and avoids abnormal signal transmission of the stacked semiconductor device structure resulted from any damage to the semiconductor devices or poor interconnection between the semiconductor devices during the stacking process, and thus further increases the yield rate of the final semiconductor package structure.

A secondary objective of the present invention is to provide a method of testing a stacked semiconductor device structure. The method of testing a stacked semiconductor device structure involves subjecting each of the semiconductor devices to the electrical testing immediately after each of the semiconductor device being stacked. The method of testing ensures that the semiconductor devices have normal electrical signals after being stacked, enables immediate stop of the stacking process, and prompt action of repairing or rework for replacement of the semiconductor devices when any abnormal electrical signal is detected during the semiconductor device stacking process, and thus prevents well-functioning semiconductor devices from being stacked on a faulty stacked semiconductor device structure so as to reduce the waste of the well-functioning semiconductor devices and lower the production cost.

Yet another objective of the present invention is to provide a method of testing a stacked semiconductor device structure. The method of testing a stacked semiconductor device structure involves subjecting each of the semiconductor devices to the electrical testing immediately after each of the semiconductor device being stacked. The testing method is simple, requires no complicated test signals, and improves the manufacturing process of the stacked semiconductor device structure efficiently.

### BRIEF DESCRIPTION OF THE SEVERAL VIEWS OF THE DRAWINGS

FIG. 1 is a flow chart of a method of testing a stacked semiconductor device structure according to a first embodiment of the present invention;

FIG. 2A is a schematic view of a testing board and a probe card according to the first embodiment of the present invention;

FIG. 2B is a schematic view of a testing board and a substrate coupled together according to the first embodiment of the present invention;

FIG. 2C is a schematic view of a semiconductor device according to the first embodiment of the present invention;

FIG. 2D is a schematic view of a substrate and a semiconductor device coupled together to be tested according to the first embodiment of the present invention;

FIG. 2E is a schematic view of a two-layer stacked semiconductor device to be tested according to the first embodiment of the present invention;

FIG. 2F is a schematic view of a four-layer stacked semiconductor device to be tested according to the first embodiment of the present invention;

FIG. 2G is a schematic view of an eight-layer stacked semiconductor device to be tested according to the first embodiment of the present invention;

FIG. 3 is a flow chart of a method of testing a stacked semiconductor device structure according to a second embodiment of the present invention;

FIG. 4A is a schematic view of a semiconductor device and a substrate coupled together according to the second embodiment of the present invention;

FIG. 4B is a schematic view of a substrate and a semiconductor device coupled together to be tested according to the second embodiment of the present invention; and

FIG. 4C is a schematic view of a two-layer stacked semiconductor device to be tested according to the second embodiment of the present invention.

### DETAILED DESCRIPTION OF THE EMBODIMENTS OF THE INVENTION

The present invention discloses a method of testing a stacked semiconductor device structure, wherein the way of testing a semiconductor device is well known by persons skilled in the art and thus is not described in detail hereunder. The drawings below, with which the description presented hereunder is illustrated, are intended to depict schematically the structures related to the features of the present invention and are not, and need not be, drawn to scale.

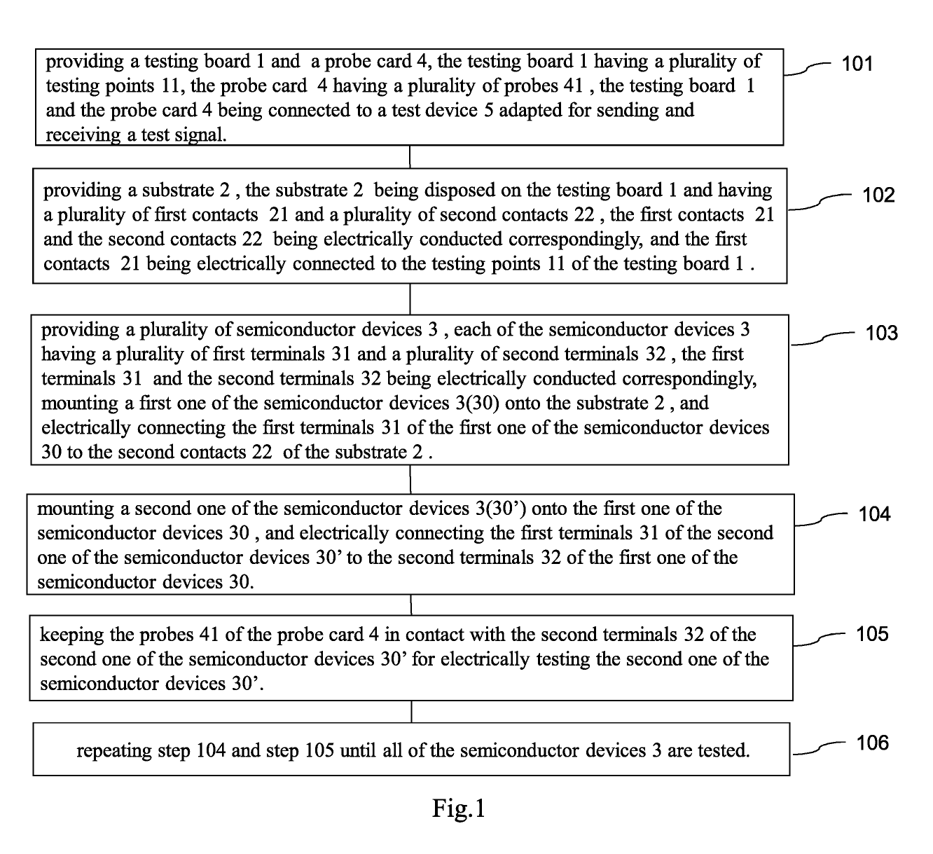

Referring to FIG. 1, there is shown a flow chart of a method of testing a stacked semiconductor device structure according to a first embodiment of the present invention. The method of testing a stacked semiconductor device structure according to a first embodiment of the present invention includes the steps described below.

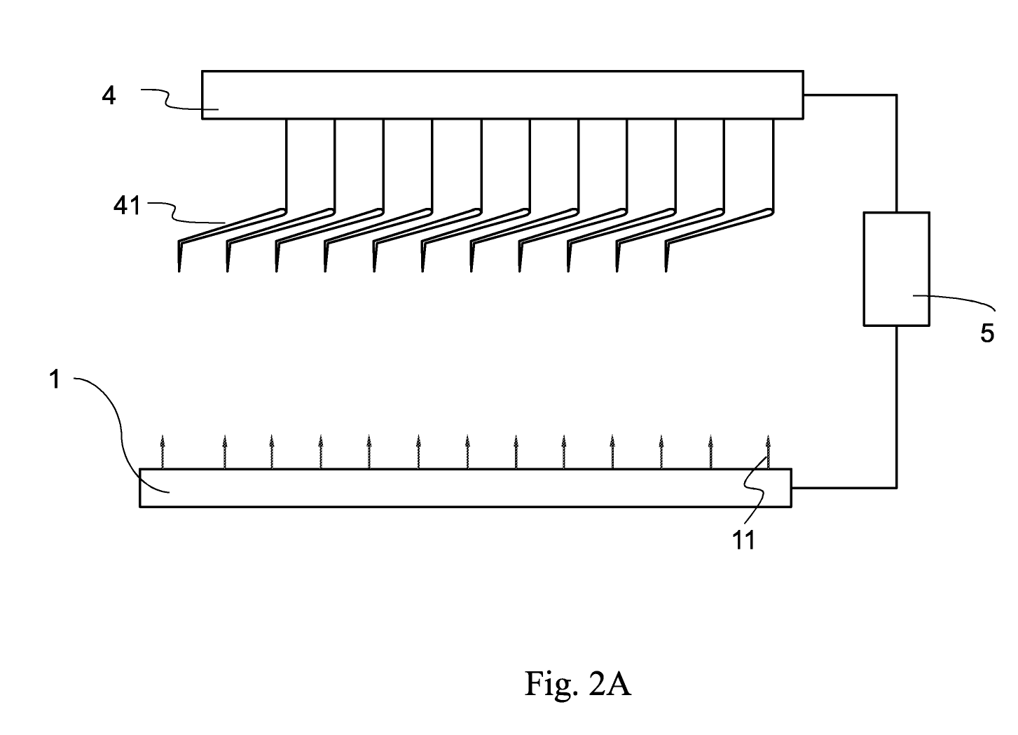

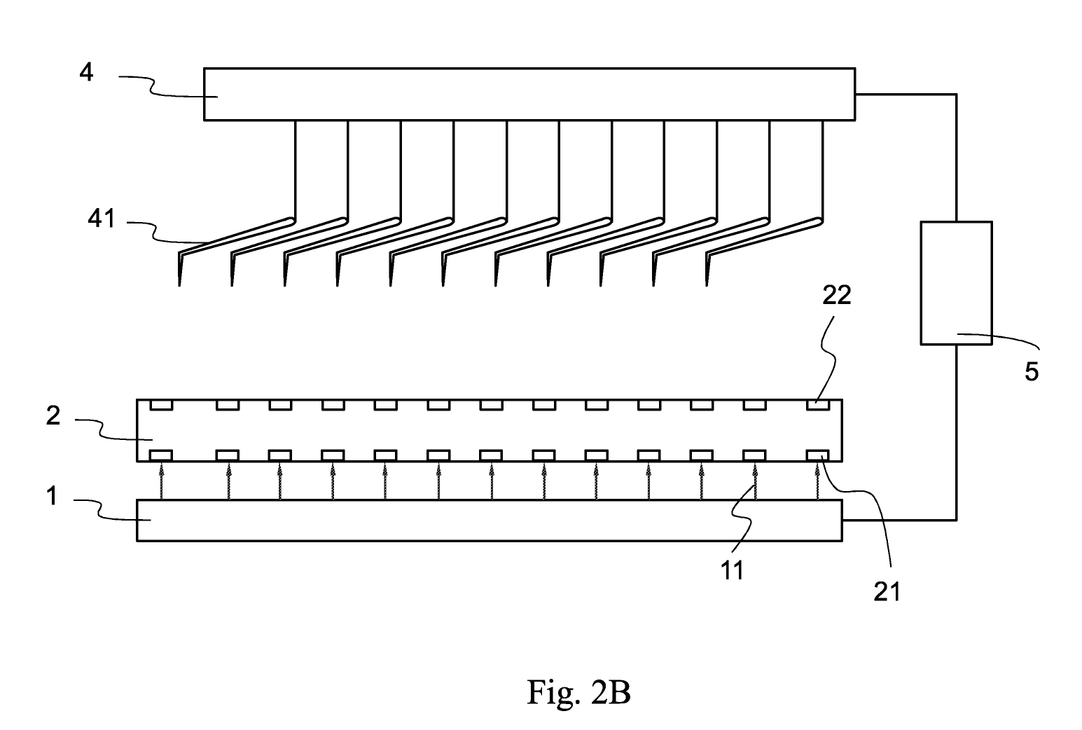

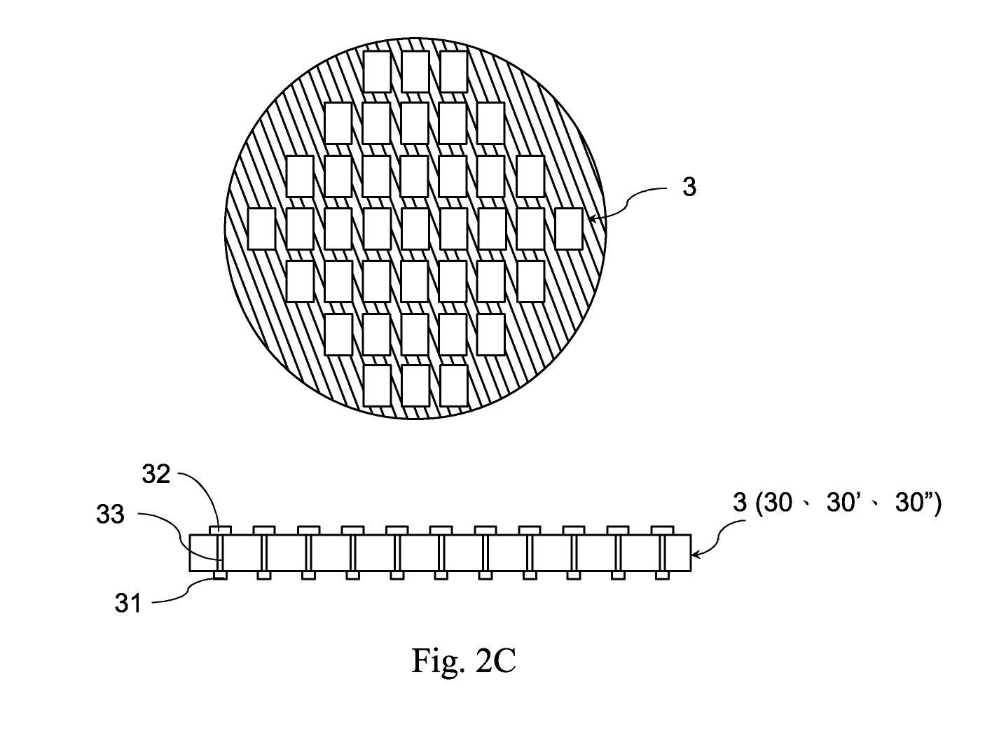

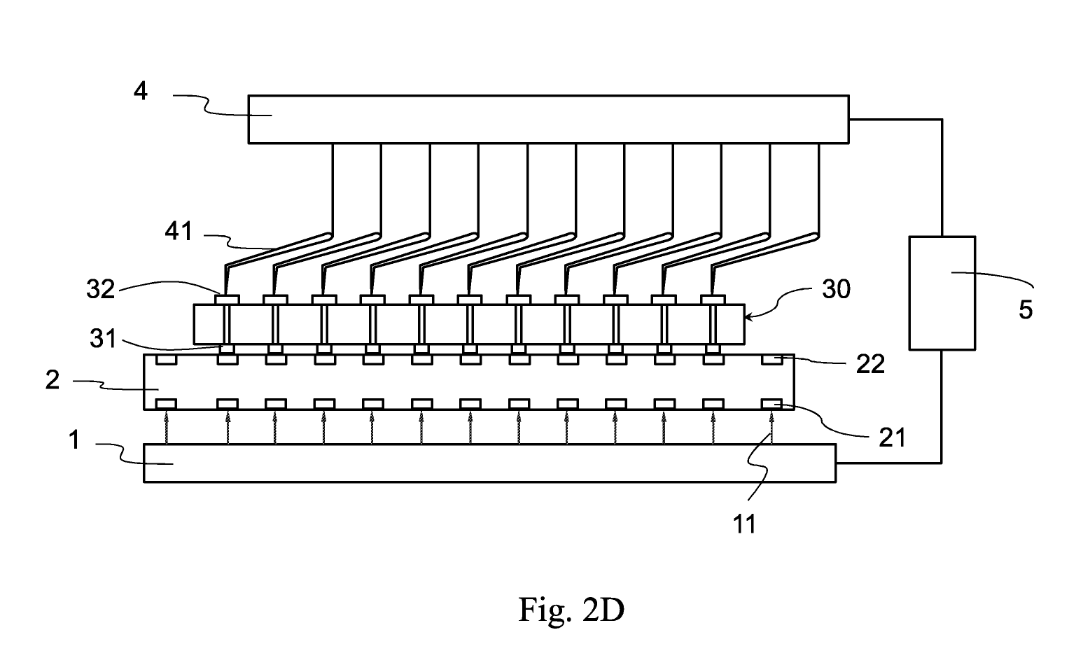

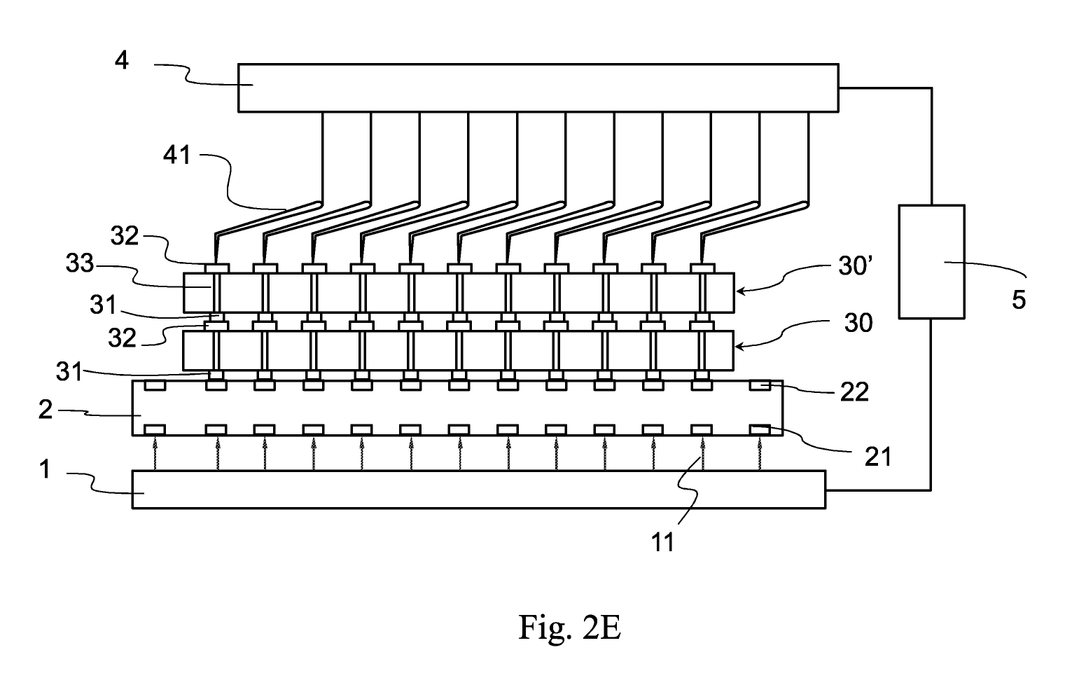

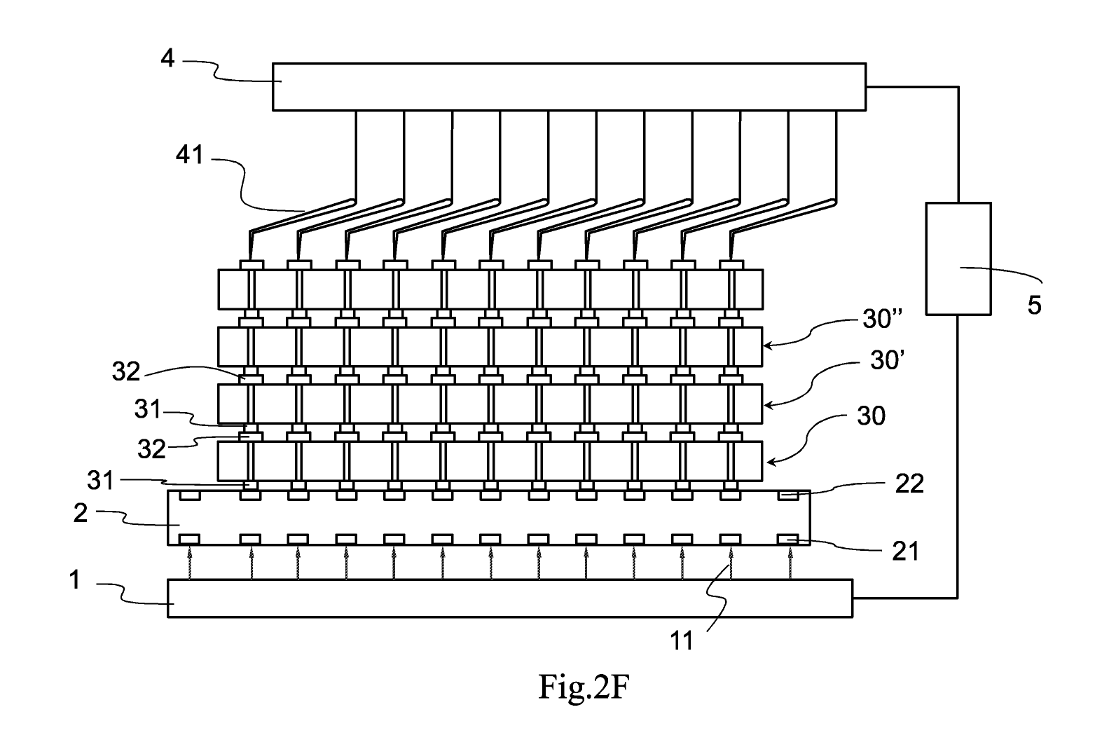

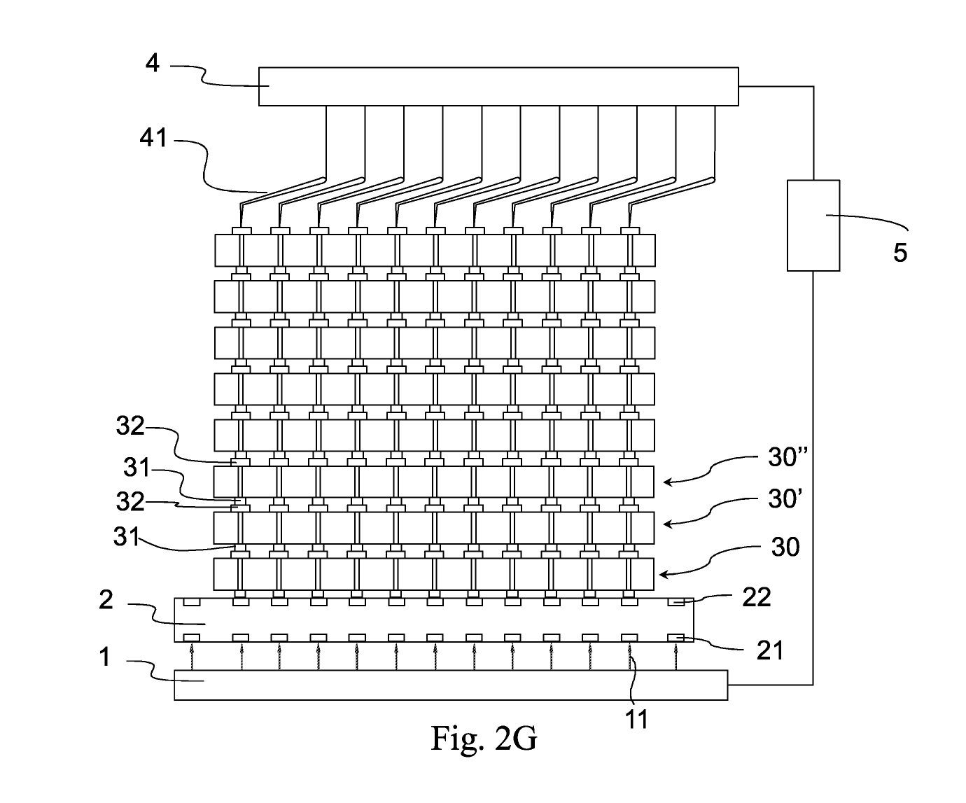

Step 101: providing a testing board 1 and a probe card 4, the testing board 1 having a plurality of testing points 11, the probe card 4 having a plurality of probes 41, the testing board 1 and the probe card 4 being respectively connected to a test device 5 adapted for sending and receiving a test signal (as shown in FIG. 2A). The testing points 11 of the testing board 1 are designed to be electrically independent of each other or to be electrically conducted with each other, depending on the testing requirements. The test device 5 can send test signals to the probe card 4 or the testing board 1, and receive the test signals fed back from the probe card 4 or the testing board 1, so as to perform electrical reading and analysis.

Step 102: providing a substrate 2, the substrate 2 being disposed on the testing board 1, the substrate 2 having a plurality of first contacts 21 and a plurality of second contacts 22, the first contacts 21 and the second contacts 22 being electrically conducted correspondingly, and the first contacts 21 being electrically connected to the testing points 11 of the testing board 1 (as shown in FIG. 2B).

Step 103: providing a plurality of semiconductor devices 3, each of the semiconductor devices 3 having a plurality of first terminals 31 and a plurality of second terminals 32, wherein the first terminals 31 and the second terminals 32 being electrically conducted correspondingly (as shown in FIG. 2C). Mounting a first one of the semiconductor devices 3 (hereinafter called first semiconductor device 30) onto the substrate 2, and electrically connecting the first terminals 31 of the first semiconductor device 30 to the second contacts 22 of the substrate 2 (as shown in FIG. 2D).

Step 104: mounting a second one of the semiconductor devices 3 (hereinafter called second semiconductor device 30′) onto the first semiconductor device 30, and electrically connecting the first terminals 31 of the second semiconductor device 30′ to the second terminals 32 of the first semiconductor device 30 (as shown in FIG. 2E). Meanwhile, if the second semiconductor device 30′, the first semiconductor device 30 and the substrate 2 are properly interconnected, a test circuit loop will be formed for performing the electrical testing.

Step 105: keeping the probes 41 of the probe card 4 in contact with the second terminals 32 of the second semiconductor device 30′ so as to test whether the second semiconductor device 30′ is electrically connected to the first semiconductor device 30 and the substrate 2, and to determine whether the second semiconductor device 30′ transmits electrical signals properly. A test signal derived from the test device 5 is received by the probe card 4 and then transmitted sequentially through the probes 41, the second semiconductor device 30′, the first semiconductor device 30, the substrate 2, and the testing board 1, and finally returned to the test device 5 for determining the electrical condition.

Step 106: repeating step 104 and step 105 (as shown in FIG. 2F and FIG. 2G) until all of the semiconductor devices 3 are tested. This step includes: mounting a third one of the semiconductor devices 3 (hereinafter called third semiconductor device 30″) onto the second semiconductor device 30′, and electrically connecting the first terminals 31 of the third semiconductor device 30″ to the second terminals 32 of the second semiconductor device 30′. Keeping the probes 41 of the probe card 4 in contact with the second terminals 32 of the third semiconductor device 30″ for electrically testing the third semiconductor device 30″ until all the semiconductor devices 3 (i.e. the fourth, fifth, sixth semiconductor devices 30″, and so on) are tested.

The method of testing a stacked semiconductor device structure according to the first preferred embodiment of the present invention further includes a step after step 102 of keeping the probes 41 of the probe card 4 in contact with the second contacts 22 of the substrate 2 for electrically testing the substrate 2. The method of testing a stacked semiconductor device structure according to the first preferred embodiment of the present invention further includes a step before step 104 of keeping the probes 41 of the probe card 4 in contact with the second terminals 32 of the first semiconductor device 30 mounted on the substrate 2 for electrically testing the first semiconductor device 30. Repeating the aforesaid mounting and testing steps ensures proper interconnections between the semiconductor devices and between the semiconductor devices and the substrate, thereby preventing subsequent problems, such as an open circuit or a short circuit. During the step-by-step testing process, it is feasible to immediately find out any semiconductor device damaged due to stacking or other problems, and therefore to replace a defective semiconductor device with a well-functioning one. This testing method may reduce the likelihood of abnormal operation of the whole stacked package structure due to any damaged semiconductor device or defective interconnection, and may increase the yield rate of the stacked semiconductor device package structure.

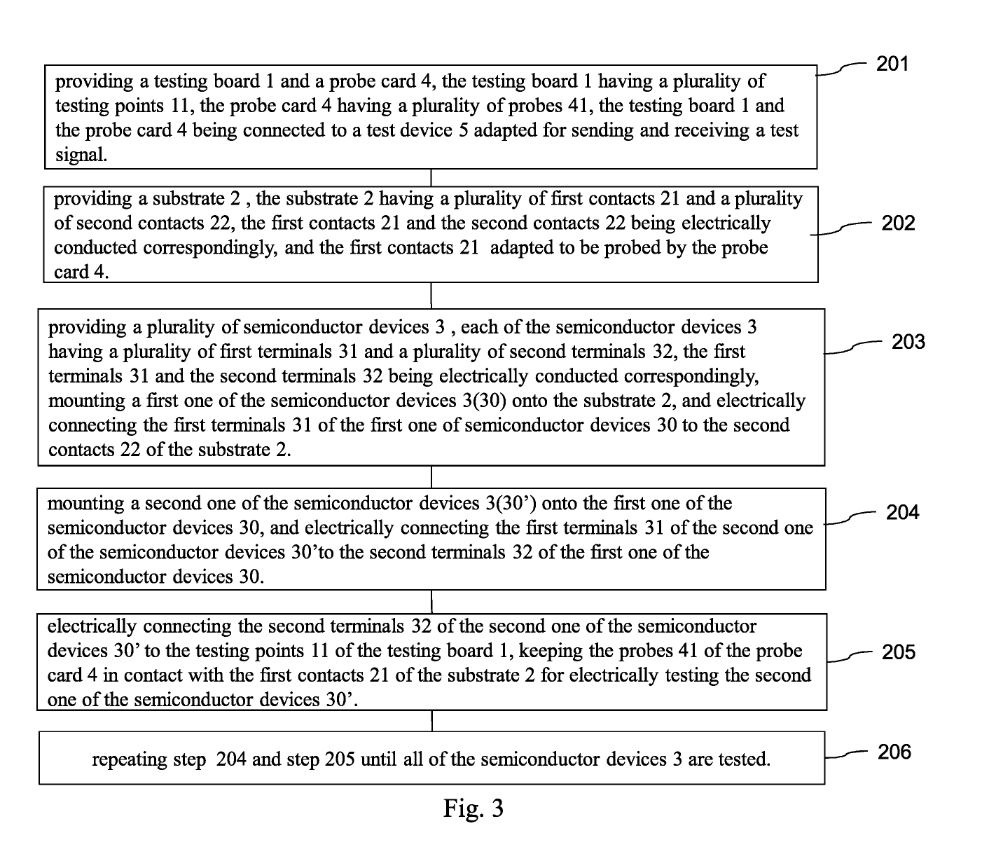

Referring to FIG. 3, there is shown a flow chart of a method of testing a stacked semiconductor device structure according to a second preferred embodiment of the present invention.

Step 201: providing a testing board 1 and a probe card 4, the testing board 1 having a plurality of testing points 11, the probe card 4 having a plurality of probes 41, the testing board 1 and the probe card 4 being respectively connected to a test device 5 adapted for sending and receiving a test signal (as shown in FIG. 2A). The testing board 1 in the second embodiment is the same as the testing board 1 in the first embodiment and thus is not described again hereunder.

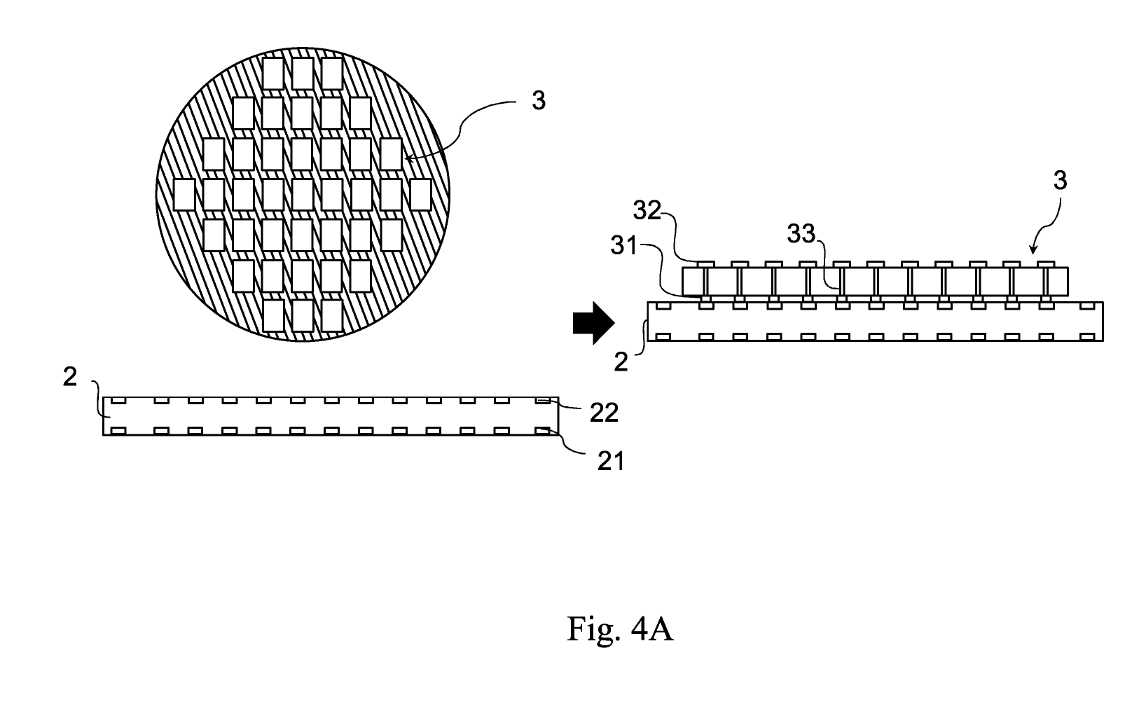

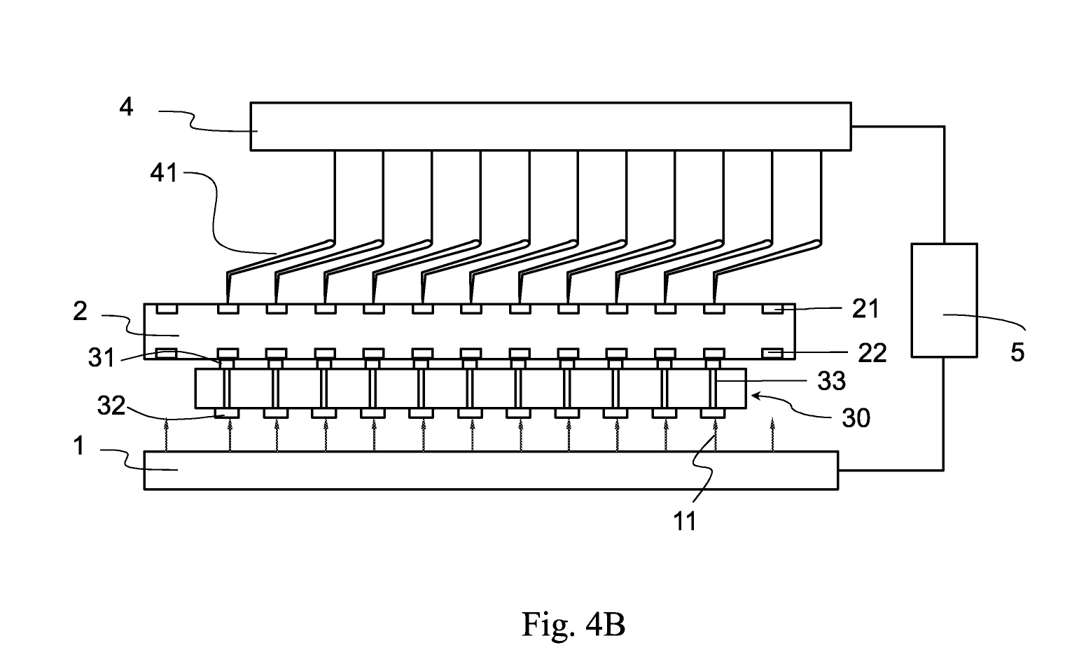

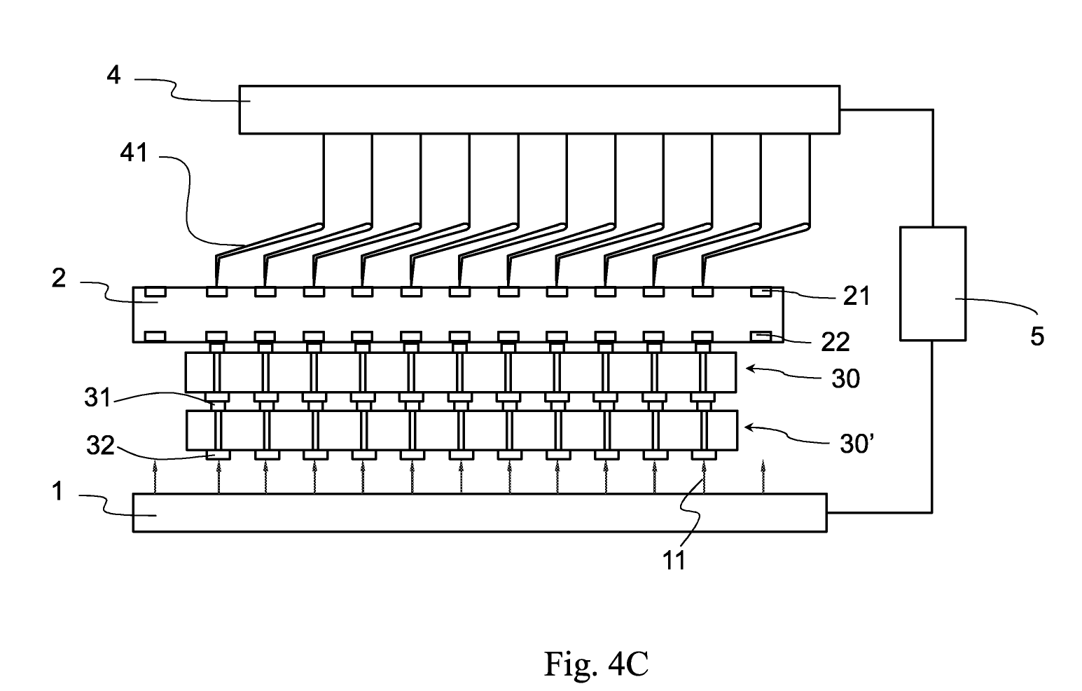

Step 202: providing a substrate 2, the substrate 2 having a plurality of first contacts 21 and a plurality of second contacts 22, the first contacts 21 and the second contacts 22 being electrically conducted correspondingly, and the first contacts 21 adapted to be probed by the probe card 4 (as shown in FIG. 4A).

Step 203: providing a plurality of semiconductor devices 3, each of the semiconductor devices 3 having a plurality of first terminals 31 and a plurality of second terminals 32, the first terminals 31 and the second terminals 32 being electrically conducted correspondingly. Mounting a first one of the semiconductor device 3 (hereinafter called first semiconductor device 30) onto the substrate 2, and electrically connecting the first terminals 31 of the first semiconductor device 30 to the second contacts 22 of the substrate 2 (as shown in FIG. 4A).

Step 204: mounting a second one of the semiconductor devices 3 (hereinafter called second semiconductor device 30′) onto the first semiconductor device 30, and electrically connecting the first terminals 31 of the second semiconductor device 30′ to the second terminals 32 of the first semiconductor device 30 (as shown in FIG. 4C).

Step 205: electrically connecting the second terminals 32 of the second semiconductor device 30′ to the testing points 11 of the testing board 1, keeping the probes 41 of the probe card 4 in contact with the first contacts 21 of the substrate 2 so as to electrically test the second semiconductor device 30′. It means that, after step 204, a stacked structure including the first semiconductor device 30, the second semiconductor device 30′ and the substrate 2 is turned over and disposed on the testing board 1. In this way, the second terminals 32 of the second semiconductor device 30′ are electrically connected with the testing points 11 of the testing board 1, meanwhile, the first contacts 21 of the substrate 2 face the probe card 4 for the probes 41 of the probe card 4 to contact therewith. Hence, it is feasible to test whether the second semiconductor device 30′ is electrically connected to the first semiconductor device 30 and the substrate 2, and to determine whether the second semiconductor device 30′ transmits electrical signals properly. A test signal derived from the test device 5 is received by the probe card 4, then transmitted sequentially through the probes 41, the substrate 2, the first semiconductor device 30, the second semiconductor device 30′ and the testing board 1, and finally returned to the test device 5 for determining the electrical condition. Upon completion of testing the second semiconductor device 30′, the stacked structure is turned over again, and is then proceeding with the subsequent mounting steps.

Step 206: repeating step 204 and step 205 (as shown in FIG. 4C) until all of the semiconductor devices 3 are tested.

The method of testing a stacked semiconductor device structure according to the second preferred embodiment of the present invention further includes a step before step 204 of electrically connecting the second terminals 32 of the first semiconductor device 30 to the testing points 11 of the testing board 1, keeping the probes 41 of the probe card 4 in contact with the first contacts 21 of the substrate 2 for electrically testing the first semiconductor device 30 (as shown in FIG. 4B). More specifically, after step 203, the mounted structure of the first semiconductor device 30 and the substrate 2 is turned over and disposed on the testing board 1 for the second terminals 32 of the first semiconductor device 30 to face the testing board 1 and to be electrically connected with the testing points 11 of the testing board 1, while the first contacts 21 of the substrate 2 face the probe card 4 for the probes 41 of the probe card 4 to contact therewith so as to test the interconnection between the first semiconductor device 30 and the substrate 2.

Each of the aforesaid semiconductor devices 3 has a plurality of through-silicon-vias (TSVs). Since the developing technology keeps moving the interconnects of TSV semiconductor devices to finer pitch, but the current fabrication technology for the probes 41 of the probe card 4 may have reached the limits and be unlikely to meet this fine pitch requirement, the second preferred embodiment provides an alternative for the test of a stacked semiconductor device structure. Since the pitch of the electrical contacts of the substrate 2 is larger than that of the interconnects of TSV semiconductor devices, the present invention puts forward a way of inverted testing to have the probe card 4 being in contact with the electrical contacts of the substrate 2, wherein the stacked structure is turned over to have the first contacts 21 of the substrate 2 facing the probe card 4 for the probes 41 to contact therewith, and the second terminals 32 of the semiconductor devices 3 to connect with the testing points 11 of the testing board 1, for the testing process.

In the first and second preferred embodiments, the testing board 1 can have an electrical potential of zero. Depending on the way of testing and the purpose of testing, all of the testing points 11 of the testing board 1 can be electrically conducted (for example, being grounded) or electrically independent of each other, or a portion of the testing points 11 are electrically conducted and another portion of the testing points 11 are electrically independent of each other. The testing board 1 can be selected from a printed circuit board, a ceramic substrate, a flexible film, a pogo pin board, a socket, or a semiconductor wafer. Furthermore, the probe card 4 can be selected from but not limited to a cantilever probe card, a vertical probe card, a pogo pin probe card, a microelectromechanical system (MEMS) probe card or any kinds that can achieve the same purpose as the above-mentioned and meet the requirements of product implementation and equipment installation correspondingly.

Furthermore, the first terminals 31 and the second terminals 32 of each of the semiconductor devices 3 are electrically conducted by through-silicon-vias (TSVs) 33 respectively (as shown in FIG. 2C). Due to limitations pertaining to downsizing and materials in the conventional packaging process, the 3D stacked packaging is considered a key technology to manufacture high-performance semiconductor devices with reduced form factors. In particular, the TSV semiconductor devices effectuate electrical interconnections between the semiconductor devices by integrating wafers/chips through vertical electrical conduction. Therefore, costs can be effectively reduced and integration and performance of the system can be enhanced.

Accordingly, the present invention provides a method of testing a stacked semiconductor device structure, which is simple and can effectively increase the yield rate and the production capability of the stacked semiconductor device structures. By contrast, the conventional method of testing a stacked semiconductor device structure is not capable to test the semiconductor devices layer by layer so that the semiconductor devices damaged by external forces during the stacking process cannot be detected immediately. It may further result in deterioration of the overall functionality of the stacked semiconductor device structure, or even the malfunction of the semiconductor devices and reduction of their service life. Therefore, the present invention not only ensures the proper performance of the semiconductor devices, increases the yield rate of the stacked structures, reduces wasted costs, provides a simple and convenient testing method, but also lowers the possibility of damage to the semiconductor devices, cuts overall manufacturing costs, and boosts productivity.

The present invention is disclosed above by preferred embodiments. However, persons skilled in the art should understand that the preferred embodiments are illustrative of the present invention only, but should not be interpreted as restrictive of the scope of the present invention. Persons skilled in the art are able to understand and implement the above disclosure of the present invention. Hence, all equivalent changes or modifications made to the aforesaid embodiments without departing from the spirit embodied in the present invention should fall within the scope of the present invention.

What is claimed is:

1. A method of testing a stacked semiconductor device structure, comprising the steps of:
(a) providing a testing board and a probe card, the testing board having a plurality of testing points, the probe card having a plurality of probes, the testing board and the probe card being respectively connected to a test device adapted for sending and receiving a test signal;
(b) providing a substrate, the substrate being disposed on the testing board and having a plurality of first contacts and a plurality of second contacts, the first contacts and the second contacts being electrically conducted correspondingly, and the first contacts being electrically connected to the testing points of the testing board;
(c) providing a plurality of semiconductor devices, each of the semiconductor devices having a plurality of first terminals and a plurality of second terminals, the first terminals and the second terminals being electrically conducted correspondingly, mounting a first one of the semiconductor devices onto the substrate, and electrically connecting the first terminals of the first one of the semiconductor devices to the second contacts of the substrate;
(d) mounting a second one of the semiconductor devices onto the first one of the semiconductor devices, and electrically connecting the first terminals of the second one of the semiconductor devices to the second terminals of the first one of the semiconductor devices;
(e) keeping the probes of the probe card in contact with the second terminals of the second one of the semiconductor devices for electrically testing the second one of the semiconductor devices; and
(f) repeating step (d) and step (e) until all of the semiconductor devices are tested.

2. The method of claim 1, further comprising a step after the step (b) of: keeping the probes of the probe card in contact with the second contacts of the substrate for electrically testing the substrate.

3. The method of claim 1, further comprising a step before the step (d) of: keeping the probes of the probe card in contact with the second terminals of the first one of the semiconductor device on the substrate for electrically testing the first one of the semiconductor device.

4. The method of claim 1, wherein the first terminals and the second terminals of each of the semiconductor devices are electrically conducted correspondingly by a plurality of through-silicon-vias (TSVs).

5. The method of claim 1, wherein all of the testing points of the testing board are electrically conducted.

6. The method of claim 5, wherein the testing board has an electrical potential of zero.

7. The method of claim 1, wherein the testing points of the testing board are electrically independent of each other.

8. A method of testing a stacked semiconductor device structure, comprising the steps of:
(a) providing a testing board and a probe card, the testing board having a plurality of testing points, the probe card having a plurality of probes, the testing board and the probe card being respectively connected to a test device adapted for sending and receiving a test signal;
(b) providing a substrate, the substrate having a plurality of first contacts and a plurality of second contacts, the first contacts and the second contacts being electrically conducted correspondingly, and the first contacts adapted to be probed by the probe card;
(c) providing a plurality of semiconductor devices, each of the semiconductor devices having a plurality of first terminals and a plurality of second terminals, the first terminals and the second terminals being electrically conducted correspondingly, mounting a first one of the semiconductor devices onto the substrate, and electrically connecting the first terminals of the first one of semiconductor devices to the second contacts of the substrate;
(d) mounting a second one of the semiconductor devices onto the first one of the semiconductor devices, and electrically connecting the first terminals of the second one of the semiconductor devices to the second terminals of the first one of the semiconductor devices;
(e) electrically connecting the second terminals of the second one of the semiconductor devices to the testing points of the testing board, keeping the probes of the probe card in contact with the first contacts of the substrate for electrically testing the second one of the semiconductor devices; and
(f) repeating step (d) and step (e) until all of the semiconductor devices are tested.

9. The method of claim 8, further comprising a step before step (d) of: electrically connecting the second terminals of the first one of the semiconductor devices to the testing points of the testing board, keeping the probes of the probe card in contact with the first contacts of the substrate for electrically testing the first one of the semiconductor devices.

10. The method of claim 8, wherein the first terminals and the second terminals of each of the semiconductor devices are electrically conducted correspondingly by a plurality of through-silicon-vias (TSVs).

11. The method of claim 8, wherein all of the testing points of the testing board are electrically conducted.

12. The method of claim 11, wherein the testing board has an electrical potential of zero.

13. The method of claim 8, wherein the testing points of the testing board are electrically independent of each other.
